(19) United States
(12) Patent Application Publication
(10) Pub. No.: US 2007/0247958 A1
(43) Pub. Date: Oct. 25, 2007

(54) Column selection signal generator for semiconductor memory

(75) Inventor: Do Yun Lee, Gyeonggi-do (KR)

Correspondence Address: VENABLE LLP, P.O. BOX 34385, WASHINGTON, DC, 20043-9998, US

(73) Assignee: Hynix Semiconductor Inc., Gyeonggi-do (KR)

(21) Appl. No.: 11/647,462

(22) Filed: Dec. 29, 2006

(30) Foreign Application Priority Data
Apr. 5, 2006 (KR) 10-2006-0030934

(51) Int. Cl. G11C 8/00

(52) U.S. Cl. 365/230.06; 365/230.08

(57) ABSTRACT

A column selection signal generator includes a timing generating unit that enables a column selection signal using a read or write command at timing according to a time control signal, a timing control unit that generates the timing control signal to control the enable timing of the column selection signal, and a pulse width generating unit that controls the column selection signal to have a prescribed pulse width and outputs a final column selection signal.

### BACKGROUND OF THE INVENTION

1. Technical Field

The present invention relates to semiconductor memory, and more particularly, to a column selection signal generator for a semiconductor memory.

2. Related Art

In general, a column selection signal (hereinafter, simply referred to as Yi) performs a very important function in a semiconductor memory. The column selection signal selects data output from the semiconductor memory. The data is output to a bit line sense amplifier. When the Yi becomes enabled at an abnormally early or late time, or an enable interval is short, the data cannot be read out or written.

As shown in FIG. 1, a column selection signal generator for a semiconductor memory according to the related art includes an OR gate OR1 that receives a column address strobe pulse (hereinafter, referred to as casp_rd) generated according to a read command, a column address strobe pulse (hereinafter, referred to as casp_wt) generated according to a write command, and a column address strobe pulse (hereinafter, referred to as icasp) generated according to a burst command, a first delay 11 that receives the output of the OR gate OR1, a first inverter IV1 that receives the output of the first delay 11, a second delay 12 that receives the output of the first inverter IV1, a NAND gate ND1 that receives the output of the first delay 11 and the second delay 12, and a second inverter IV2 that receives the output of the NAND gate ND1 and outputs the Yi.

The operation of the column selection signal generator for a semiconductor memory according to the related art that has the above-described structure will be described below.

When a read or write command is input to the semiconductor memory, a column address strobe pulse according to a corresponding column address is generated.

As a result, a high-level signal is output through the OR gate OR1, and is then delayed by the first delay 11.

The enable timing of the Yi is determined by the delay time of the first delay 11.

The output of the first delay 11 is inverted by the first inverter IV1, and is then delayed by the second delay 12.

A logical product is performed on the output of the first delay 11 and the output of the second delay 12 by the NAND gate ND1, the product is inverted by the second inverter IV2, and the Yi is output.

A pulse width of the Yi is determined by the delay time of the second delay 12.

As described above, in the column selection signal generator for a semiconductor memory according to the related art, the enable timing and the pulse width of the Yi are determined by using the delay elements whose delay time is determined in advance.

Although, a plurality of chips are manufactured by the same processes, the characteristics of a chip may be different according to the location of the chip on a wafer and a size of the lot.

As described above, according to the related art, since the enable timing and the pulse width of the column selection signal are fixed, the column selection signal generator cannot cope with variations in chip characteristics. Further, the column selection signal timing must be accurate or an enable interval cannot be maintained for a necessary time, which causes a data output error.

### SUMMARY

Embodiments of the present invention provide a column selection signal generator for a semiconductor memory that is capable of generating an optimal column selection signal according to variations in chip characteristics.

A first embodiment of the present invention provides a column selection signal generator for a semiconductor, memory, which may include a timing generating unit that enables a column selection signal using a read or write command at a time according to a timing control signal, a timing control unit that generates the timing control signal to control the enable timing of the column selection signal, and a pulse width generating unit that controls the column selection signal to have a prescribed pulse width and outputs a final column selection signal.

Another embodiment of the present invention provides a column selection signal generator for a semiconductor memory, which may include a timing generating unit that enables a column selection signal using a read or write command a prescribed time, a pulse width generating unit that controls the column selection signal to have a pulse width according to a pulse width control signal and outputs a final column selection signal, and a pulse width control unit that generates the pulse width control signal to control the pulse width of the column selection signal.

A third embodiment of the present invention provides a column selection signal generator for a semiconductor memory, which may include a timing generating unit that enables a column selection signal using a read or write command at a time according to a timing control signal, a timing control unit that generates the timing control signal to control the enable timing of the column selection signal, a pulse width generating unit that controls the column selection signal to have a pulse width according to a pulse width control signal and outputs a final column selection signal, and a pulse width control unit that generates the pulse width control signal to control the pulse width of the column selection signal.

### BRIEF DESCRIPTION OF THE DRAWINGS

FIG. 1 is a circuit diagram illustrating the structure of a column selection signal generator for a semiconductor memory according to the related art;

FIG. 2 is a block diagram illustrating the structure of a column selection signal generator for a semiconductor memory according to a first embodiment of the present invention;

FIG. 3 is a circuit diagram illustrating the structure of a timing generating unit of FIG. 2;

FIG. 4 is a circuit diagram illustrating the structure of a timing control unit of FIG. 2;

FIG. 5 is a circuit diagram illustrating the structure of a pulse width generating unit of FIG. 2;

FIG. 6 is a circuit diagram illustrating the structure of an error detecting unit of FIG. 2;

FIG. 7 is a block diagram illustrating the structure of a column selection signal generator for a semiconductor memory according to a second embodiment of the present invention;

FIG. 8 is a circuit diagram illustrating the structure of a timing generating unit of FIG. 7;

FIG. 9 is a circuit diagram illustrating the structure of a pulse width generating unit of FIG. 7;

FIG. 10 is a circuit diagram illustrating the structure of a pulse width control unit of FIG. 7; and

FIG. 11 is a block diagram illustrating the structure of a column selection signal generator for a semiconductor memory according to a third embodiment of the present invention.

### DESCRIPTION OF EXEMPLARY EMBODIMENTS

Embodiments of the present invention will now be described in detail with reference to the accompanying drawings.

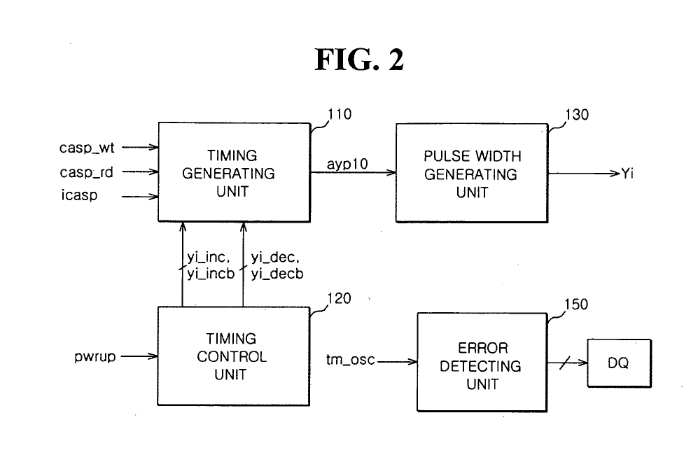

Referring to FIG. 2, a column selection signal generator for a semiconductor memory according to a first embodiment of the present invention may include a timing generating unit 110 that enables a column selection signal (hereinafter, simply referred to as Yi) using a signal generated according to a read or write command at a time according to a timing control signal, a timing control unit 120 that generates the timing control signal to control the enable timing of the Yi, a pulse width generating unit 130 that controls the Yi enabled by the timing generating unit 110 to have a prescribed pulse width and outputs a final Yi, and an error detecting unit 150 that generates a sample signal so as to detect an error in at least one of the enable timing or the pulse width of the Yi.

The signals that are generated according to the read or write command include a column address strobe pulse (hereinafter, referred to as casp_rd) generated according to a read command, a column address strobe pulse (hereinafter, referred to as casp_wt) generated according to a write command, and a column address strobe pulse (hereinafter, referred to as icasp) generated according to a burst command.

The timing control signal includes timing increase signals yi_inc and yi_incb that allow the enable timing of the Yi to be later than the prescribed timing, and timing decrease signals yi_dec and yi_decb that allow the enable timing of the Yi to be earlier than the prescribed timing.

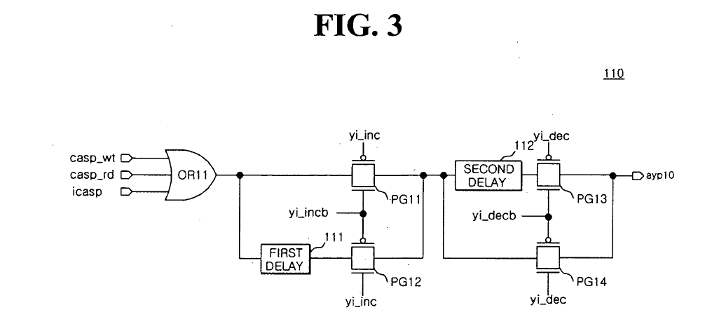

As shown in FIG. 3, the timing generating unit 110 includes an OR gate OR11 that receives the casp_rd, casp_wt, and icasp; a first pass gate PG11 that receives the output of the OR gate OR11; a first delay 111 that receives the output of the OR gate OR11; a second pass gate PG12 that receives the output of the first delay 111; a second delay 112 that receives the output of the first pass gate PG11 or the second pass gate PG12; a third pass gate PG13 that receives the output of the second delay 112; and a fourth pass gate PG14 that receives the output of the first pass gate PG11 or the second pass gate PG12. A timing signal (hereinafter, referred to as ayp10) is output through the third pass gate PG13 or the fourth pass gate PG14.

The first pass gate PG11 has a first control terminal that receives the yi_inc, and a second control terminal that receives the yi_incb. The second pass gate PG12 has a first control terminal that receives the yi_incb, and a second control terminal that receives the yi_inc. The third pass gate PG13 has a first control terminal that receives the yi_dec and a second control terminal that receives yi_decb. The fourth pass gate PG14 has a first control terminal that receives the yi_decb and a second control terminal that receives the yi_dec.

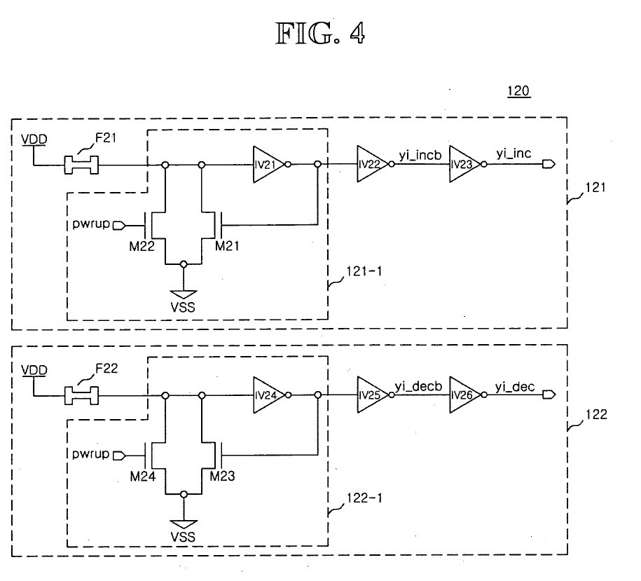

As shown in FIG. 4, the timing control unit 120 includes a timing increase control unit 121 that generates the timing increase signals yi_inc and yi_incb, and a timing decrease control unit 122 that generates the timing decrease signals yi_dec and yi_decb.

The timing increase control unit 121 includes a first fuse F21 having a first end coupled to a power supply terminal VDD, a first level maintaining unit 121-1 coupled to a second end of the first fuse F21, a first inverter IV22 that receives the output of the first level maintaining unit 121-1, and a second inverter IV23 that receives the output of the first inverter IV22. The first level maintaining unit 121-1 includes a third inverter IV21 having an input terminal coupled to the second end of the fuse F21 and an output terminal coupled to the first inverter IV22; a first transistor M21 having a drain coupled to an input terminal of the third inverter IV21, a source coupled to a ground, and a gate coupled to an output terminal of the third inverter IV21; and a second transistor M22 having a drain coupled to the drain of the first transistor M21, a source coupled to a ground, and a gate receiving a driving signal, that is, a power up signal pwrup.

The timing decrease control unit 122 includes a second fuse F22 having a first end is coupled to a power supply terminal VDD, a second level maintaining unit 122-1 that is coupled to a second end of the second fuse F22, a fourth inverter IV25 that receives the output of the second level maintaining unit 122-1, and a fifth inverter IV26 that receives the output of the fourth inverter IV25. The second level maintaining unit 122-1 includes a sixth inverter IV24 having an input terminal coupled to the second end of the second fuse F22 and having an output terminal coupled to the fourth inverter IV25; a third transistor M23 having a drain coupled to an input terminal of the sixth inverter IV24 having a source coupled to a ground, and a gate coupled to the output terminal of the sixth inverter IV24; and a fourth transistor M24 having a drain coupled to the drain of the third transistor M23, a source coupled to a ground, and a gate receiving a driving signal, that is, a power up signal pwrup.

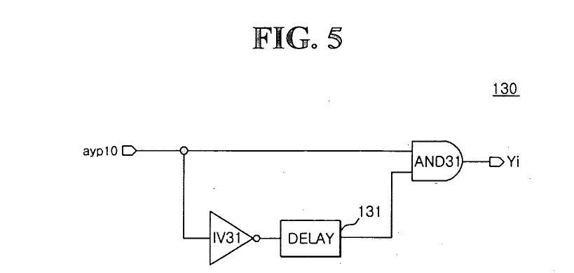

As shown in FIG. 5, the pulse width generating unit 130 includes an inverter IV31 that receives the ayp10 output by the timing generating unit 110, a delay 131 that receives output of the inverter IV31, and an AND gate AND31 that receives the ayp10 and the output of the delay 131 and outputs Yi having a prescribed pulse width.

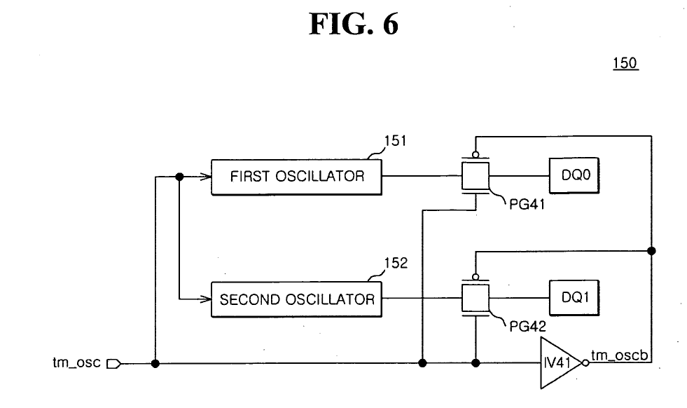

As shown in FIG. 6, the error detecting unit 150 includes first and second oscillators 151 and 152 that receive a test mode signal (hereinafter, referred to as tm_osc), and first and second pass gates PG41 and PG42 that transmit the respective outputs of the first and second oscillators 151 and 152 in accordance with the tm_osc and tm_oscb inverted by an inverter IV41 to the prescribed pads DQ0 and DQ1, or intercept it therefrom. The error detecting unit 150 shown in FIG. 6 that has a structure including two oscillators and two pass gates is only exemplary, and the number of each of the oscillators and the pass gates may be increased according to the number of pads applicable in a test mode. Also, it is preferable that all of the oscillators forming the error detecting unit have the same basic output characteristic. However, the basic output characteristics may be different from each other.

An example of the operation of the column selection signal generator of the semiconductor memory according to the first embodiment of the present invention that has the above-described structure will now be described.

First, an operator places the semiconductor memory into a test mode such that the tm_osc is enabled and a timing error of the Yi is detected through the error detecting unit 150.

That is, if the tm_osc becomes enabled, the first and second oscillators 151 and 152 that are included in the error detecting unit 150 of FIG. 6 oscillate to generate periodic waveforms. For the first and second oscillators 151 and 152, oscillators that have the same basic output characteristic are used.

The first and second pass gates PG41 and PG42 of the error detecting unit 150 are turned on by the high-level tm_osc and the low-level tm_oscb. Therefore, the output waveforms of the first and second oscillators 151 and 152 are output to test equipment outside the semiconductor memory though the prescribed pads DQ0 and DQ1. Then, the operator measures a transition timing average value of the output waveforms using the test equipment and compares the measured the transition timing average value with transition timing according to the basic output characteristics of the first and second oscillators 151 and 152. According to the comparison result, a timing error, that is, whether the transition timing of the waveform is late or early is detected. At this time, since the first and second oscillators 151 and 152 are configured in the semiconductor memory, even though the output waveforms of the first and second oscillators 151 and 152 are different from the Yi, timing deviations thereof are the same. Therefore, determining whether the transition timing of the output waveform of the oscillator is late or early may be replaced by determining whether the transition timing of the Yi is late or early. Further, in a state where the above-described error detecting unit 150 is not separately provided, a method may be used in which a predetermined signal is generated by using a test mode set in advance in the semiconductor memory. However, like the error detecting unit 150 according to the first embodiment of the present invention, it is preferable to use a method in which a plurality of uniform waveforms are generated by using a plurality of oscillators, and an average value thereof is used, in terms of a more accurate timing measurement.

As such, if a timing error of the Yi is detected, the first fuse F21 or the second fuse F22 of the timing control unit 120 shown in FIG. 4 is cut, such that the timing increase signals yi_inc and yi_incb or the timing decrease signals yi_dec and yi_decb are generated during operation in a normal mode.

For example, when it is determined that the Yi becomes enabled abnormally fast, the first fuse F21 of the timing increase control unit 121 of FIG. 4 is cut. Then, when the semiconductor memory operates in a normal mode and the power up signal pwrup becomes enabled, the second transistor M22 of the first level maintaining unit 121-1 is turned on so the output level of the third inverter IV21 becomes high level. As the output level of the third inverter IV21 becomes high level, the first transistor M21 is turned on, and an input level of the third inverter IV21 is latched to a low level. As a result, an output level of the first level maintaining unit 121-1 is maintained at a high level. Therefore, the yi_incb and the yi_inc become enabled. That is, the yi_incb is output at a low level through the first inverter IV22, and the yi_inc is output at a high level through the second inverter IV23.

Meanwhile, since the second fuse F22 of the timing decrease control unit 122 is not cut, an output level of the second level maintaining unit 122-1 is maintained to a low level. Accordingly, the yi_decb and the yi_dec are outputted in high and low levels, respectively.

The yi_incb and the yi_inc are at low and high levels, respectively, and the yi_decb and the yi_dec are at high and low levels, respectively. Therefore, the second pass gate PG12 and the third pass gate PG13 of the timing generating unit 110 shown in FIG. 3 are turned on, which forms a signal path reaching an output terminal through the first delay 111, the second pass gate PG12, the second delay 112, and the third pass gate PG13.

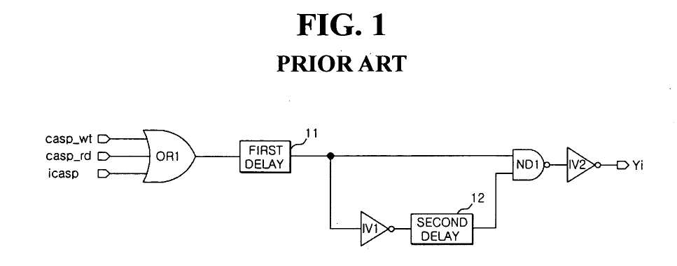

The second delay 112 may have the same delay time as the first delay 11 of FIG. 1. Meanwhile, the first delay 111 is a delay that has a longer delay time compared with the delay according to the related art, and may have the same delay time as the second delay 112 or have a different delay time according to a product design. Accordingly, the signal path enables the Yi at later time than the default time.

Then, if any one of the casp_rd, the casp_wt, and the icasp become enabled, a high-level signal is generated by the OR gate OR11 and is then delayed by a delay time corresponding to the first delay 111 and the second delay 112 through the signal path, and output as the ayp10.

Accordingly, the pulse width generating unit 130 of FIG. 5 receives the ayp10, and outputs the Yi that has a pulse width of a time corresponding to the delay 131. That is, the ayp10 and the signal that is inverted by the inverter IV31 and delayed by the delay 131 are processed as a logical product by the AND gate AND31, and the Yi is output.

As another example, when it is determined that the Yi becomes enabled at later time than the normal time, the second fuse F22 of the timing decrease control unit 122 shown in FIG. 4 is cut. Then, if the semiconductor memory operates in a normal mode and the power up signal pwrup becomes enabled, the yi_decb and the yi_dec are output at low and high levels, respectively, and the yi_incb and the yi_inc are output at high and low levels, respectively.

The yi_decb and the yi_dec are at low and high levels, respectively, and the yi_incb and the yi_inc are at high and low levels. As a result, the first pass gate PG11 and the fourth pass gate PG14 of the timing generating unit 110 shown in FIG. 3 are turned on, which forms a signal path that does not pass through the first delay 111 and the second delay 112.

Therefore, since the signal path does not pass through the first delay 111 and the second delay 112, the Yi is enabled at time earlier than the default time.

Then, if any one of the casp_rd, the casp_wt, and the icasp become enabled, a high-level signal is generated by the OR gate OR11, which then passes through the signal path, and the ayp10 is outputted.

Accordingly, the pulse width generating unit 130 of FIG. 5 receives the ayp10, and outputs the Yi that has a pulse width of a time corresponding to the delay 131.

As another example, when it is determined that the Yi becomes enabled at the normal time, the first fuse F21 and the second fuse F22 of FIG. 4 are not cut. Then, if the semiconductor memory operates in a normal mode, the yi_incb and the yi_inc are output at high and low levels, respectively, and the yi_decb and the yi_dec are also output at high and low levels, respectively.

The yi_incb and the yi_inc are at high and low levels, respectively, and the yi_decb and the yi_dec are at high and low levels, respectively. As a result, the first pass gate PG11 and the third pass gate PG13 of the timing generating unit 110 shown in FIG. 3 are turned on, which forms a signal path that reaches an output terminal through the first pass gate PG11, the second delay 112, and the third pass gate PG13.

Therefore, the signal path enables the Yi at the default time. That is, the signal path enables the Yi at an enable timing delayed by the time corresponding to the second delay 112.

Then, if any one of the casp_rd, the casp_wt, and the icasp become enabled, a high-level signal is generated by the OR gate OR11 and then delayed by a delay time corresponding to the second delay 112 through the signal path, which outputs the ayp10.

Accordingly, the pulse width generating unit 130 of FIG. 5 receives the ayp10, and outputs the Yi that has a pulse width of a time corresponding to the delay 131. That is, the ayp10, and the signal that is inverted by the inverter IV31 and is then delayed by the delay 131 are processed as a logical product by the AND gate AND31, and the Yi is output.

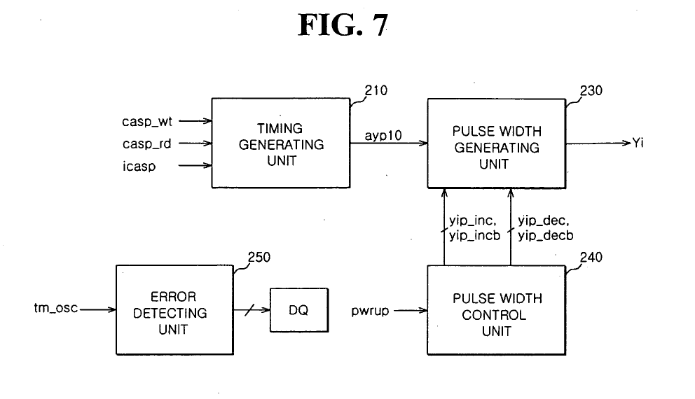

As shown in FIG. 7, a column selection signal generator for a semiconductor memory according to a second embodiment of the present invention includes a timing generating unit 210 that enables the Yi at a prescribed time using a signal generated according to a read or write command, a pulse width generating unit 230 that controls the Yi enabled by the timing generating unit 210 to have a pulse width according to a pulse width control signal and outputs a final Yi, a pulse width control unit 240 that generates the pulse width control signal to control the pulse width of the Yi, and an error detecting unit 250 that generates a sample signal so as to detect an error in at least one of the enable timing or the pulse width of the Yi.

The signals that are generated according to the read or write command include the casp_rd, the casp_wt, and the icasp.

The pulse width control signals include pulse width increase signals yip_inc and yip_incb that allow the enable pulse width of the Yi to be larger than a prescribed pulse width, and pulse width decrease signals yip_dec and yip_decb that allow the pulse width of the Yi to be smaller than the prescribed pulse width.

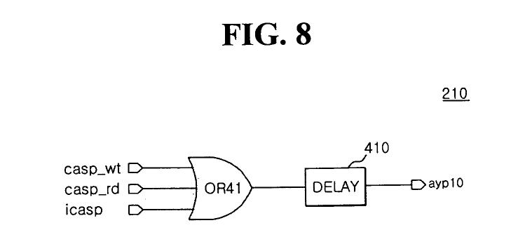

As shown in FIG. 8, the timing generating unit 210 includes an OR gate OR41 that receives the casp_rd, casp_wt, and icasp, and a delay 410 that receives the output of the OR gate OR41 and outputs ayp10.

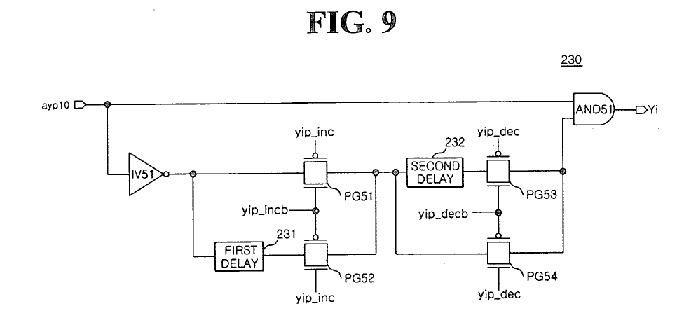

As shown in FIG. 9, the pulse width generating unit 230 includes an inverter IV51 that receives the ayp10, a first pass gate PG51 that receives the output of the inverter IV51, a first delay 231 that receives the output of the inverter IV51, a second pass gate PG52 that receives the output of the first delay 231, a second delay 232 that receives the output of the first pass gate PG51 or the second pass gate PG52, a third pass gate PG53 that receives the output of the second delay 232, a fourth pass gate PG54 that receives the output of the first pass gate PG51 or the second pass gate PG52, and an AND gate AND51 that receives the ayp10 and the output of the third pass gate PG53 or the fourth pass gate PG54 and outputs the Yi.

The first pass gate PG51 has a first control terminal that receives the yip_inc, and a second control terminal that receives the yip_incb. The second pass gate PG52 has a first control terminal that receives the yip_incb, and a second control terminal that receives the yip_inc. The third pass gate PG53 has a first control terminal that receives the yip_dec and a second control terminal that receives yip_decb. The fourth pass gate PG54 has a first control terminal that receives the yip_decb and a second control terminal that receives the yip_dec.

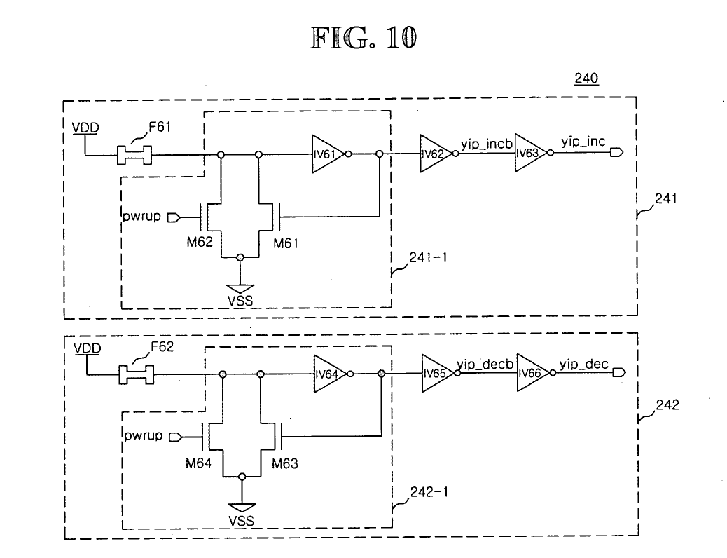

As shown in FIG. 10, the pulse width control unit 240 includes a pulse width increase control unit 241 that generates the pulse width increase signals yip_inc and yip_incb, and a pulse width decrease control unit 242 that generates the pulse width decrease signals yip_dec and yip_decb.

The pulse width increase control unit 241 includes a first fuse F61 having a first end coupled to a power supply terminal VDD; a first level maintaining unit 241-1 that is coupled to a second end of the first fuse F61; a first inverter IV62 that receives the output of the first level maintaining unit 241-1; and a second inverter IV63 that receives the output of the first inverter IV62. The first level maintaining unit 241-1 includes a third inverter IV61 having an input terminal coupled to the second end of the first fuse F61 and an output terminal coupled to the first inverter IV62, a first transistor M61 having a drain coupled to an input terminal of the third inverter IV61, a source coupled to a ground, and a gate coupled to an output terminal of the third inverter IV61, and a second transistor M62 having a drain coupled to the drain of the first transistor M61, a source coupled to a ground, and a gate receiving a driving signal, that is, a power up signal pwrup.

The pulse width decrease control unit 242 includes a second fuse F62 having a first end coupled to a power supply terminal VDD, a second level maintaining unit 242-1 that is coupled to a second end of the second fuse F62, a fourth inverter IV65 that receives the output of the first level maintaining unit 242-1, and a fifth inverter IV66 that receives the output of the fourth inverter IV65. The first level maintaining unit 242-1 includes a sixth inverter IV64 having an input terminal coupled to the second end of the second fuse F62 and an output terminal coupled to the fourth inverter IV65, a third transistor M63 having a drain coupled to an input terminal of the sixth inverter IV64, a source coupled to a ground, and a gate coupled to the output terminal of the sixth inverter IV64, and a fourth transistor M64 having a drain coupled to the drain of the third transistor M63, a source coupled to a ground, and a gate receiving a driving signal, that is, a power up signal pwrup.

The error detecting unit 250 can have the same structure as that shown in FIG. 6.

An example of the operation of the column selection signal generator of the semiconductor memory according to the second embodiment of the present invention that has the above-described structure will now be described.

First, an operator places the semiconductor memory into a test mode such that the tm_osc is enabled and a pulse width error of the Yi is detected through the error detecting unit 250.

That is, as the tm_osc becomes enabled, a plurality of oscillator output waveforms that are output by the error detecting unit 250 are output to test equipment outside the semiconductor memory though prescribed pads. Then, the operator measures a pulse width average value of the output waveforms using the test equipment and compares the measured pulse width average value with a pulse width according to the prescribed basic output characteristics of the oscillators. According to the comparison result, it is detected whether the pulse width increases or decreases. At this time, since the oscillators are configured in the semiconductor memory, even though the output waveforms of the oscillators are different from the Yi, pulse width deviations thereof are equal to each other. Therefore, determining whether the pulse width of the output waveform of the oscillator increases or decreases may be replaced by determining whether the pulse width of the Yi increases or decreases. Further, in a state where the above-described error detecting unit 250 is not separately provided, a method may be used in which a predetermined signal is generated by using a test mode set in advance in the semiconductor memory. However, like the error detecting unit 250 according to the second embodiment of the present invention, it is preferable to use a method in which a plurality of uniform waveforms are generated by using a plurality of oscillators, and an average value thereof is used, in terms of a more accurate pulse width measurement.

As such, if a pulse width error of the Yi is detected, the first fuse F61 or the second fuse F62 of the pulse width control unit 240 shown in FIG. 10 is cut, such that the pulse width increase signals yip_inc and yip_incb or the pulse width decrease signals yip_dec and yip_decb are generated at the time of an operation in a normal mode.

For example, when it is determined that the pulse width of the Yi is smaller than a normal pulse width, the first fuse F61 of the pulse width increase control unit 241 of FIG. 10 is cut. Then, when the semiconductor memory operates in a normal mode and the power up signal pwrup becomes enabled, the second transistor M62 of the first level maintaining unit 241-1 is turned on so as to allow an output level of the third inverter IV61 to become a high level. As the output level of the third inverter IV61 becomes a high level, the first transistor M61 is turned on, and an input level of the third inverter IV61 is latched to a low level. As a result, an output level of the first level maintaining unit 241-1 is maintained at a high level. Accordingly, the yip_incb is output at a low level through the first inverter IV62, and the yip_inc is output at a high level through the second inverter IV63.

Meanwhile, since the second fuse F62 of the pulse width decrease control unit 242 is not cut, an output level of the second level maintaining unit 242-1 is maintained at a low level. Accordingly, the yip_decb and the yip_dec are output at high and low levels, respectively.

Then, if any one of the casp_rd, the casp_wt, and the icasp become enabled, a high-level signal is generated by the OR gate OR41 shown in FIG. 8 and is then delayed by a prescribed time by the delay 410, and the ayp10 is output.

The yip_incb and the yip_inc are at, low and high levels, respectively, and the yip_decb and the yip_dec are at high and low levels, respectively. As a result, the second pass gate PG52 and the third pass gate PG53 that are included in the pulse width generating unit 230 shown in FIG. 9 are turned on, which forms a signal path that reaches an output terminal through the first delay 231, the second pass gate PG52, the second delay 232, and the third pass gate PG53. The signal path makes the pulse width of the Yi larger than the default pulse width.

Accordingly, the ayp10 is inverted by the inverter IV51 of the pulse width generating unit 230, and is then delayed through the signal path. In addition, the AND gate AND51 performs a logical product on the output of the third pass gate PG53 and the ayp10, and outputs the Yi that has a pulse width larger than the default pulse width. The second delay 232 may have the same delay time as the first delay 11 of FIG. 1. Meanwhile, the first delay 231 is a delay that may have a longer delay time compared with the delay according to the related art, and its delay time may be set according to a particular product design.

As another example, when it is determined that the pulse width of the Yi is larger than a normal pulse width, the second fuse F62 of the pulse decrease control unit 242 shown in FIG. 10 is cut. Then, if the semiconductor memory operates in a normal mode and the power up signal pwrup becomes enabled, the yip_decb and the yip_dec are output at low and high levels, respectively, and the yi_incb and the yi_inc are outputted in high and low levels, respectively.

Then, if any one of the casp_rd, the casp_wt, and the icasp becomes enabled, a high-level signal is generated by the OR gate OR41 of FIG. 8 and is then delayed by a prescribed time by the delay 410, and the ayp10 is output.

The yip_decb and the yip_dec are at low and high levels, respectively, and the yip_incb and the yip_inc are at high and low levels, respectively. As a result, the first pass gate PG51 and the fourth pass gate PG54 that are included in the pulse width generating unit 230 shown in FIG. 9 are turned on, which forms a signal path that does not pass through the first delay 231 and the second delay 232. Since the signal path does not pass through the first delay 231 and the second delay 232, the signal path makes the pulse width of the Yi smaller than the default pulse width.

Accordingly, the ayp10 is inverted by the inverter IV51 of the pulse width generating unit 230, and is then delayed through the signal path. In addition, the AND gate AND51 performs a logical product on the output of the fourth pass gate PG54 and the ayp10, and outputs the Yi that has a pulse width smaller than the default pulse width.

As another example, when it is determined that the Yi becomes enabled at normal time, the first fuse F61 and the second fuse F62 shown in FIG. 10 are not cut. Then, if the semiconductor memory operates in a normal mode, the yip_incb and the yip_inc are output at high and low levels, respectively, and the yip_decb and the yip_dec are also output at high and low levels, respectively.

Then, if any one of the casp_rd, the casp_wt, and the icasp become enabled, a high-level signal is generated by the OR gate OR41 of FIG. 8 and is then delayed by a prescribed time by the delay 410, and the ayp10 is output.

The yip_incb and the yip_inc are at high and low levels, respectively, and the yip_decb and the yip_dec are at high and low levels, respectively. As a result, the first pass gate PG51 and the third pass gate PG53 of the pulse width generating unit 230 shown in FIG. 9 are turned on, which forms a signal path that reaches an output terminal through the first pass gate PG51, the second delay 232, and the third pass gate PG53. The signal path makes the pulse width of the Yi equal to the default pulse width.

Therefore, the ayp10 is inverted by the inverter IV51 of the pulse width generating unit 230 and is delayed through the signal path. In addition, the AND gate AND51 performs a logical product on the output of the third pass gate PG53 and the ayp10, and outputs the Yi having the default pulse width.

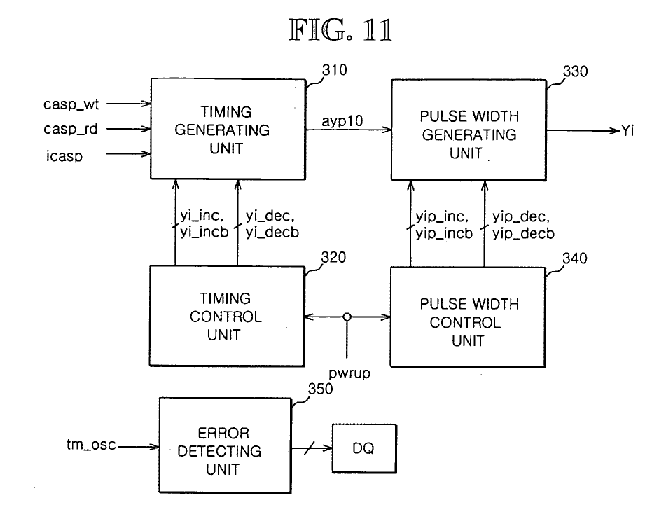

As shown in FIG. 11, a column selection signal generator for a semiconductor memory according to a third embodiment of the present invention may include a timing generating unit 310 that enables the Yi using a signal generated according to a read or write command at a time according to a timing control signal, a timing control unit 320 that generates the timing control signal to control the enable timing of the Yi, a pulse width generating unit 330 that controls the Yi enabled by the timing generating unit 310 to have a pulse width according to the pulse width control signal and outputs a final Yi, a pulse width control unit 340 that generates the pulse width control signal to control the pulse width of the Yi, and an error detecting unit 350 that generates a sample signal so as to detect an error in at least one of the enable timing or the pulse width of the Yi.

The timing generating unit 310 may have the same structure as that shown in FIG. 3, the timing control unit 320 may have the same structure as that shown in FIG. 4, the pulse width generating unit 330 may have the same structure as that shown in FIG. 9, and the pulse width control unit 340 may have the same structure as that shown in FIG. 10. Therefore, the description thereof will be omitted.

An example of the operation of the column selection signal generator of the semiconductor memory according to the third embodiment of the present invention that has the above-described structure will now be described.

First, an operator places the semiconductor memory into a test mode such that the tm_osc is enabled and timing and pulse width errors of the Yi are detected through the error detecting unit 350. That is, if the tm_osc becomes enabled, a plurality of oscillator output waveforms that are output by the error detecting unit 350 are output to test equipment outside the semiconductor memory through prescribed pads. Then, the operator measures the enable timing and a pulse width average value of the output waveforms using the test equipment, and compares the measured enable timing and pulse width average value with enable timing and a pulse width according to prescribed basic output characteristics of oscillators. According to the result of the comparison, it is detected whether the timing is early or late and whether the pulse width increases or decreases. At this time, since the oscillators are configured in the semiconductor memory, even though the output waveforms of the oscillators are different from that of the Yi, the oscillators have the same timing and pulse width deviation. Therefore, the timing and the pulse width error of the oscillator output waveform may be replaced by the timing and the pulse width error of the Yi. Further, in a state where the above-described error detecting unit 350 is not separately provided, a method may be used in which a predetermined signal is generated by using a test mode set in advance in the semiconductor memory. However, like the error detecting unit 350 according to the third embodiment of the present invention, it is preferable to use a method in which a plurality of uniform waveforms are generated by using a plurality of oscillators, and an average value thereof is used, in terms of a more accurate timing and pulse width measurement.

As such, if timing and pulse width errors of the Yi are detected, the fuses of the timing control unit 320 and the fuses of the pulse width control unit 340 are selectively cut such that the detected errors are corrected, making it possible to generate at least one of the timing increase signals yi_inc and yi_incb, the timing decrease signals yi_dec and yi_decb, the pulse width increase signals yip_inc and yip_incb, and the pulse width decrease signals yip_dec and yip_decb during operation in a normal mode. As a result of error detection, when there is no problem, the above-described signals related to the timing and the pulse widths are not generated.

Among the timing increase signals yi_inc and yi_incb, the timing decrease signals yi_dec and yi_decb, the pulse width increase signals yip_inc and yip_incb, and the pulse width decrease signals yip_dec and yip_decb, the generated signals are supplied to the timing generating unit 310 and the pulse width generating unit 330.

Accordingly, at least one of the enable timing or the pulse width of the Yi is adjusted by the timing generating unit 310 and the pulse width generating unit 330. Since the process of adjusting the enable timing and the pulse width of the Yi has been described in detailed in the first and second embodiments, the repetitive description will be omitted.

According to the first and second embodiment of the present invention, the enable timing or the pulse width of the column selection signal may be adjusted so as to generate optimal column selection signals based on the characteristic deviation of the semiconductor memory. Further, according to the third embodiment of the present invention, the enable timing and the pulse width of the column selection signal may be simultaneously adjusted, thereby generating a further stable column selection signal.

It will be apparent to those skilled in the art that various modifications and changes may be made without departing from the scope and spirit of the present invention. Therefore, it should be understood that the above embodiments are not limiting, but illustrative in all aspects. The scope of the invention is defined by the appended claims rather than by the description preceding them, and therefore all changes and modifications that fall within the metes and bounds of the claims, or equivalents of such metes and bounds are therefore intended to be embraced by the claims.

According to the embodiments of the present invention, a column selection signal generator for a semiconductor memory tests the characteristic variations in a process of the semiconductor memory, and adjusts the enable timing and a pulse width of the column selection signal. Accordingly, since an optimal column selection signal can be generated without depending on the characteristic variation in a process of the semiconductor memory, the reliability of input and output data can be improved, and performance of the semiconductor memory can be improved.

What is claimed is:

1. A column selection signal generator for a semiconductor memory, the generator comprising:
a timing generating unit configured to enable a column selection signal based on a read or write command and a timing control signal;
a timing control unit configured to generate the timing control signal to control enable timing of the column selection signal; and
a pulse width generating unit configured to modify the column selection signal to have a prescribed pulse width and to output a final column selection signal.

2. The generator of claim 1,
wherein the timing generating unit includes:
a logic element configured to receive at least two signals generated in accordance with the read or write command and to produce an output based thereon;
a first switch configured to receive the output of the logic element and to provide an output;
a first delay element configured to receive the output of the logic element and to provide an output;
a second switch configured to receive the output of the first delay element and to provide an output;
a second delay element configured to receive the output of the first switch or the second switch and to provide an output;
a third switch configured to receive the output of the second delay element; and
a fourth switch configured to receive the output of the first switch or the second switch.

3. The generator of claim 2,
wherein delay times of the first delay element and the second delay element are the same.

4. The generator of claim 2,
wherein the first to fourth switches comprise pass gates.

5. The generator of claim 1,
wherein the timing control unit includes:
a timing increase control unit configured to generate a timing increase signal; and
a timing decrease control unit configured to generate a timing decrease signal.

6. The generator of claim 5,
wherein the timing increase control unit includes:
a fuse having a first end coupled to a power supply terminal and a second end;
a level maintaining unit coupled to the second end of the fuse and having an output;
a first inverter configured to receive the output of the level maintaining unit and output an inverted timing increase signal; and
a second inverter configured to receive the output of the first inverter and output the timing increase signal.

7. The generator of claim 5,
wherein the timing decrease control unit includes:
a fuse having a first end coupled to a power supply terminal;
a level maintaining unit coupled to the second end of the fuse and having an output;
a first inverter configured to receive the output of the level maintaining unit and output an inverted timing decrease signal; and
a second inverter configured to receive the output of the first inverter and output the timing decrease signal.

8. The generator of claim 6,
wherein the level maintaining unit includes:
a third inverter having an input terminal coupled to the second end of the fuse and an output terminal coupled to the first inverter; and
a first transistor having a drain coupled to the input terminal of the third inverter, a source coupled to ground, and a gate coupled to the output terminal of the third inverter.

9. The generator of claim 8, further comprising:
a second transistor having a drain coupled to the drain of the first transistor, a source coupled to ground, and a gate receiving a driving signal.

10. The generator of claim 9,
wherein the driving signal comprises a power up signal.

11. The generator of claim 7,
wherein the level maintaining unit includes:
a third inverter having an input terminal coupled to the second end of the fuse and an output terminal coupled to the first inverter; and
a first transistor having a drain coupled to the input terminal of the third inverter, a source coupled to ground, and a gate coupled to the output terminal of the third inverter.

12. The generator of claim 11, further comprising:
a second transistor having a drain coupled to the drain of the first transistor, a source coupled to ground, and a gate configured to receive a driving signal.

13. The generator of claim 12,
wherein the driving signal comprises a power up signal.

14. The generator of claim 1,
wherein the pulse width generating unit includes:
an inverter configured to receive the column selection signal and to produce an output;
a delay element configured to receive the output of the inverter and to produce an output; and
an AND gate configured to receive the column selection signal and the output of the delay element.

15. The generator of claim 1, further comprising:
an error detecting unit configured to generate a sample signal to detect at least one error in the enable timing or the pulse width of the column selection signal.

16. The generator of claim 15,
wherein the error detecting unit includes:
at least one oscillator configured to receive a test mode signal and to provide an output; and
at least one switching element configured to transmit the output of the at least one oscillator to a predetermined pad or intercept the output of the at least one oscillator in accordance with the test mode signal.

17. The generator of claim 16,
wherein there are more than one oscillator having the same basic output characteristic.

18. The generator of claim 16,
wherein the switching element comprises a pass gate.

19. The generator of claim 1,
wherein the column selection signal is enabled when the timing control signal is enabled.

20. A column selection signal generator for a semiconductor memory, the generator comprising:
a timing generating unit configured to enable a column selection signal using a read or write command at a prescribed timing;
a pulse width generating unit configured to modify the column selection signal to have a pulse width according to a pulse width control signal and output a final column selection signal; and
a pulse width control unit configured to generate the pulse width control signal to control the pulse width of the column selection signal.

21. The generator of claim 20,
wherein the timing generating unit includes:
a logic element configured to receive at least two signals generated in accordance with the read or write command and to produce an output based thereon; and
a delay element configured to receive the output of the logic element.

22. The generator of claim 20,
wherein the pulse width generating unit includes:
an inverter configured to receive the column selection signal and to provide an output;
a first switch configured to receive the output of the inverter and to provide an output;
a first delay element configured to receive the output of the inverter and to provide an output;
a second switch configured to receive the output of the first delay element and to provide an output;
a second delay element configured to receive the output of the first switch or the second switch and to provide an output;
a third switch configured to receive the output of the second delay element and to provide an output;
a fourth switch configured to receive the output of the first switch or the second switch and to provide an output; and
a logic element configured to receive the output of the timing generating unit and the output of the third switch or the fourth switch.

23. The generator of claim 22,
wherein delay times of the first delay element and the second delay element are the same.

24. The generator of claim 22,
wherein the first to fourth switches comprise pass gates.

25. The generator of claim 20,
wherein the pulse width control unit includes:
a pulse width increase control unit configured to generate a pulse width increase signal; and
a pulse width decrease control unit configured to generate a pulse width decrease signal.

26. The generator of claim 25,
wherein the pulse width increase control unit includes:
a fuse having a first end coupled to a power supply terminal and a second end;
a level maintaining unit coupled to the second end of the fuse;
a first inverter configured to receive the output of the level maintaining unit and output an inverted pulse width increase signal; and
a second inverter configured to receive the output of the first inverter and output the pulse width increase signal.

27. The generator of claim 25,
wherein the pulse width decrease control unit includes:
a fuse having a first end coupled to a power supply terminal;
a level maintaining unit coupled to the second end of the fuse;
a first inverter configured to receive the output of the level maintaining unit and output an inverted pulse width decrease signal; and
a second inverter configured to receive the output of the first inverter and output the pulse width decrease signal.

28. The generator of claim 26,
wherein the level maintaining unit includes:
a third inverter having an input terminal coupled to the second end of the fuse and an output terminal coupled to the first inverter;
a first transistor having a drain coupled to the input terminal of the third inverter, a source coupled to ground, and a gate coupled to the output terminal of the third inverter; and
a second transistor having a drain coupled to the drain of the first transistor, a source coupled to ground, and a gate configured to receive a driving signal.

29. The generator of claim 28,
wherein the driving signal comprises a power up signal.

30. The generator of claim 27,
wherein the level maintaining unit includes:
a third inverter having an input terminal coupled to the second end of the fuse and an output terminal coupled to the first inverter; and
a first transistor having a drain coupled to the input terminal of the third inverter, a source coupled to ground, and a gate coupled to the output terminal of the third inverter; and
a second transistor having a drain coupled to the drain of the first transistor, a source coupled to ground, and a gate configured to receive a driving signal.

31. The generator of claim 30,
wherein the driving signal comprises a power up signal.

32. The generator of claim 20, further comprising:
an error detecting unit configured to generate a sample signal to detect at least one error in the enable timing or the pulse width of the column selection signal.

33. The generator of claim 32,
wherein the error detecting unit includes:
at least one oscillator configured to receive a test mode signal and to produce an output; and
at least one switching element configured to transmit the output of the at least one oscillator to a predetermined, pad or intercept the output of the least one oscillator in accordance with the test mode signal.

34. The generator of claim 33,
wherein there are more than one oscillator having the same basic output characteristic.

35. The generator of claim 33,
wherein the switching element comprises a pass gate.

36. A column selection signal generator for a semiconductor memory, the generator comprising:
a timing generating unit configured to enable a column selection signal using a read or write command at time according to a timing control signal;
a timing control unit configured to generate the timing control signal to control the enable timing of the column selection signal;
a pulse width generating unit configured to modify the column selection signal to have a pulse width according to a pulse width control signal and output a final column selection signal; and
a pulse width control unit configured to generate the pulse width control signal to control the pulse width of the column selection signal.

37. The generator of claim 36,
wherein the timing generating unit includes:
a logic element configured to receive at least two signals generated in accordance with the read or write command and to produce an output based thereon;
a first switch configured to receive the output of the logic element and to provide an output;
a first delay element configured to receive the output of the logic element and to provide an output;
a second switch configured to receive the output of the first delay element and to provide an output;
a second delay element configured to receive the output of the first switch or the second switch and to provide an output;
a third switch configured to receive the output of the second delay element; and
a fourth switch configured to receive the output of the first switch or the second switch.

38. The generator of claim 37,
wherein delay times of the first delay element and the second delay element are the same.

39. The generator of claim 37,
wherein the first to fourth switches comprise pass gates.

40. The generator of claim 36,
wherein the timing control unit includes:
a timing increase control unit configured to generate a timing increase signal; and
a timing decrease control unit configured to generate a timing decrease signal.

41. The generator of claim 40,
wherein the timing increase control unit includes:
a fuse having a first end coupled to a power supply terminal;
a level maintaining unit coupled to the second end of the fuse and having an output;
a first inverter configured to receive the output of the level maintaining unit and output an inverted timing increase signal; and
a second inverter configured to receive the output of the first inverter and output the timing increase signal.

42. The generator of claim 41,
wherein the level maintaining unit includes:
a third inverter having an input terminal coupled to the second end of the fuse and an output terminal coupled to the first inverter;
a first transistor having a drain coupled to the input terminal of the third inverter, a source coupled to ground, and a gate coupled to the output terminal of the third inverter; and
a second transistor having a drain coupled to the drain of the first transistor, a source coupled to a ground, and a gate configured to receive a driving signal.

43. The generator of claim 42,
wherein the driving signal comprises a power up signal.

44. The generator of claim 40,
wherein the timing decrease control unit includes:
a fuse having a first end coupled to a power supply terminal;
a level maintaining unit coupled to the second end of the fuse and having an output;
a first inverter configured to receive the output of the level maintaining unit and output an inverted timing decrease signal; and
a second inverter configured to receive the output of the first inverter and output the timing decrease signal.

45. The generator of claim 44,
wherein the level maintaining unit includes:
a third inverter having an input terminal coupled to the second end of the fuse and an output terminal coupled to the first inverter;
a first transistor having a drain coupled to the input terminal of the third inverter, a source coupled to a ground, and a gate coupled to the output terminal of the third inverter; and
a second transistor having a drain coupled to the drain of the first transistor, a source coupled to a ground, and a gate configured to receive a driving signal.

46. The generator of claim 45,
wherein the driving signal comprises a power up signal.

47. The generator of claim 36,
wherein the pulse width generating unit includes:
an inverter configured to receive the column selection signal output of the timing generating unit and to provide an output;
a first switch configured to receive the output of the inverter and to provide an output;
a first delay element configured to receive the output of the inverter and to provide an output;
a second switch configured to receive the output of the first delay element and to provide an output;
a second delay element configured to receive the output of the first switch or the second switch and to provide an output;
a third switch configured to receive the output of the second delay element and to provide an output;
a fourth switch configured to receive the output of the first switch or the second switch and to provide an output; and
a logic element configured to receive the column selection signal and the output of the third switch or the fourth switch.

48. The generator of claim 47,
wherein delay times of the first delay element and the second delay element are the same.

49. The generator of claim 47,
wherein the first to fourth switches comprise pass gates.

50. The generator of claim 36,
wherein the pulse width control unit includes:
a pulse width increase control unit configured to generate a pulse width increase signal; and
a pulse width decrease control unit configured to generate a pulse width decrease signal.

51. The generator of claim 50,
wherein the pulse width increase control unit includes:
a fuse having a first end coupled to a power supply terminal;
a level maintaining unit coupled to the second end of the fuse and having an output;
a first inverter configured to receive the output of the level maintaining unit and output an inverted pulse width increase signal; and
a second inverter configured to receive the output of the first inverter and output the pulse width increase signal.

52. The generator of claim 51,
wherein the level maintaining unit includes:
a third inverter having an input terminal coupled to the second end of the fuse and an output terminal coupled to the first inverter;
a first transistor having a drain coupled to the input terminal of the third inverter, a source coupled to ground, and a gate coupled to the output terminal of the third inverter; and
a second transistor having a drain coupled to the drain of the first transistor, a source coupled to a ground, and a gate configured to receive a driving signal.

53. The generator of claim 52,
wherein the driving signal comprises a power up signal.

54. The generator of claim 50,
wherein the pulse width decrease control unit includes:
a fuse having a first end coupled to a power supply terminal and a second end;
a level maintaining unit coupled to the second end of the fuse and having an output;
a first inverter configured to receive the output of the level maintaining unit and output an inverted pulse width decrease signal; and
a second inverter configured to receive the output of the first inverter and output the pulse width decrease signal.

55. The generator of claim 54,
wherein the level maintaining unit includes:
a third inverter having an input terminal coupled to the second end of the fuse and an output terminal coupled to the first inverter;
a first transistor having a drain coupled to the input terminal of the third inverter, a source coupled to ground, and a gate coupled to the output terminal of the third inverter; and
a second transistor having a drain coupled to the drain of the first transistor, a source coupled to ground, and a gate configured to receive a driving signal.

56. The generator of claim 55,
wherein the driving signal comprises a power up signal.

57. The generator of claim 36, further comprising:
an error detecting unit configured to generate a sample signal to detect at least one error in the enable timing or the pulse width of the column selection signal.

58. The generator of claim 57,
wherein the error detecting unit includes:
at least one oscillator configured to receive a test mode signal and to produce an output; and
at least one switching element configured to transmit the output of the at least one oscillator to a predetermined pad or intercept the output of the at least in oscillator in accordance with the test mode signal.

59. The generator of claim 58,
wherein there is more than one oscillator having the same prescribed output characteristic.

60. The generator of claim 58,
wherein the switching element comprises a pass gate.
